(19) United States
(12) Patent Application Publication
(10) Pub. No.: US 2016/0021744 A1
(43) Pub. Date: Jan. 21, 2016

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Yong Ho BAEK, Suwon-Si (KR); Young Gwan KO, Suwon-Si, Gyeonggi-Do (KR); Jung Hyun CHO, Suwon-Si (KR); Jae Ean LEE, Suwon-Si (KR); Jae Hoon CHOI, Suwon-Si (KR); Jung Hyun PARK, Suwon-Si (KR)

(21) Appl. No.: 14/735,870

(22) Filed: Jun. 10, 2015

(30) Foreign Application Priority Data
Jul. 21, 2014 (KR) 10-2014-0091766

(51) Int. Cl. H05K 1/11; H05K 3/40; H05K 3/00; H05K 3/10

(52) U.S. Cl. CPC H05K 1/111; H05K 3/10; H05K 3/4038; H05K 3/0044

(57) ABSTRACT

A printed circuit board includes a first circuit pattern embedded in an insulating layer so that an upper surface of the first circuit pattern is exposed to one surface of the insulating layer, a coupling pad embedded in the insulating layer to come into contact with a lower surface of the first circuit pattern, and a bump pad formed on the upper surface of the first circuit pattern to protrude from one surface of the insulating layer.

### CROSS-REFERENCE TO RELATED APPLICATION

This application claims the priority and benefit of Korean Patent Application No. 10-2014-0091766 filed on Jul. 21, 2014, with the Korean Intellectual Property Office, the disclosure of which is incorporated herein by reference.

### BACKGROUND

The present disclosure relates to a printed circuit board and a method of manufacturing the same.

A printed circuit board is commonly manufactured by forming a circuit pattern on an insulating material using a conductive material such as copper. As electronic products have been miniaturized and thinned, a printed circuit board having an embedded pattern structure in which the circuit pattern is embedded has been used.

### SUMMARY

An aspect of the present disclosure may provide a printed circuit board having improved connectivity with a mounted component, or the like, while having an embedded pattern structure in which a circuit pattern is stably embedded and a method of manufacturing the same.

According to an aspect of the present disclosure, a printed circuit board may include: a first circuit pattern embedded in an insulating layer so that an upper surface of the first circuit pattern is exposed to one surface of the insulating layer, a coupling pad embedded in the insulating layer to come into contact with a lower surface of the first circuit pattern, and a bump pad formed on the upper surface of the first circuit pattern to protrude from one surface of the insulating layer.

The bump pad may have a shape in which a lower surface of the bump pad adjacent to the first circuit pattern is wider than an area of an upper surface of the bump pad.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view showing a structure of a printed circuit board according to an exemplary embodiment of the present disclosure;

FIG. 2 is an enlarged cross-sectional view of part ‘A’ of FIG. 1;

FIG. 3 is a partial cross-sectional view showing a structure of a coupling pad according to another exemplary embodiment of the present disclosure;

FIG. 4 is a partial cross-sectional view showing a structure of a coupling pad according to another exemplary embodiment of the present disclosure;

FIG. 5 is a cross-sectional view showing a structure of a printed circuit board according to another exemplary embodiment of the present disclosure; and

FIGS. 6 through 23 are views sequentially showing a method of manufacturing a printed circuit board according to an exemplary embodiment of the present disclosure.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Printed Circuit Board

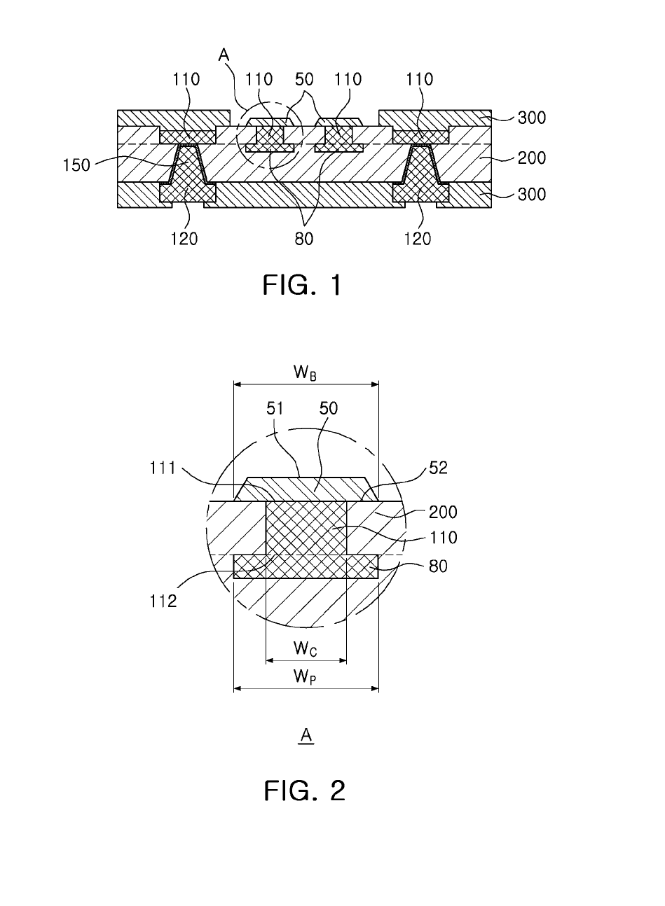

FIG. 1 is a cross-sectional view showing a structure of a printed circuit board according to an exemplary embodiment of the present disclosure.

Referring to FIG. 1, the printed circuit board according to an exemplary embodiment of the present disclosure may include an insulating layer 200, a first circuit pattern 110 embedded in the insulating layer 200 so that an upper surface thereof is exposed to one surface of the insulating layer 200, a coupling pad 80 embedded in the insulating layer 200 to come into contact with the first circuit pattern 110, and a bump pad 50 formed on the first circuit pattern 110 to protrude from one surface of the insulating layer 200.

According to the related art, a defect that an embedded circuit pattern is detached at the time of assembly has frequently occurred. The reason for the defect is that the embedded circuit pattern is partially over-etched during a process of etching a metal plate in order to form an embedded pattern structure in which the circuit pattern is embedded in an insulating layer, thereby generating a step and a crevice between the insulating layer and the embedded circuit pattern.

Therefore, according to an exemplary embodiment of the present disclosure, the circuit pattern may not be detached but be stably embedded at the time of assembly by forming the coupling pad 80 so as to come into contact with a lower surface of the first circuit pattern 100 embedded in the insulating layer 200.

Meanwhile, the upper surface of the first circuit pattern 110 exposed to one surface of the insulating layer 200 may be positioned on the same plane as one surface of the insulating layer 200 or positioned lower than one surface of insulating layer 200 due to a step generated between the insulating layer and the embedded circuit pattern.

In the first circuit pattern 110 embedded on the same level or a level lower than one surface of the insulating layer 200 as described above, a connection defect may occur at the time of mounting an electronic component such as an integrated circuit (IC), or the like. Particularly, in the case in which the first circuit pattern 110 is positioned lower than the insulating layer 200, a probability of the connection defect may be further increased.

Therefore, in the printed circuit board according to an exemplary embodiment of the present disclosure, the bump pad 50 may be selectively formed on the upper surface of portions of the embedded first circuit pattern 110.

Since the bump pad 50 is formed so as to protrude from one surface of the insulating layer 200, connectivity with a mounted component, or the like, may be improved.

A second circuit pattern 120 may be disposed on the other surface opposing one surface of the insulating layer 200, a via 150 may penetrate through the insulating layer 200 to connect the first and second circuit patterns 110 and 120 to each other may be disposed.

A resin insulating layer may be used as the insulation layer 200. As materials of the resin insulating layer, a thermosetting resin such as an epoxy resin, a thermoplastic resin such as a polyimide resin, a resin having a reinforcement material such as a glass fiber or an inorganic filler impregnated in them, for example, a prepreg may be used. However, the present disclosure is not specifically limited thereto.

Any material may be used in the first and second circuit patterns 110 and 120 without limitation as long as it is used as a conductive metal for a circuit pattern. For example, copper (Cu) may be used.

The via 150 may be formed of the same material as that of the first and second circuit patterns 110 and 120. For example, the via 150 may be formed of copper (Cu), but is not necessarily limited thereto. That is, any metal may be used without limitation as long as it is used as a conductive metal.

A solder resist 300 formed so as to expose circuit patterns for a connection pad among the first and second circuit patterns 110 and 120 may be disposed on a surface of the printed circuit board.

FIG. 2 is an enlarged cross-sectional view of part ‘A’ of FIG. 1.

Referring to FIG. 2, the bump pad 50 may be formed on the upper surface 111 of the first circuit pattern 110 to protrude from one surface of the insulating layer 200.

When a surface adjacent to the upper surface 111 of the first circuit pattern 110 is defined as a lower surface 52 of the bump pad 50, a surface opposing the lower surface 52 is defined as an upper surface 51 of the bump pad 50, the lower surface 52 may be formed to have an area wider than that of the upper surface 51.

The lower surface 52 of the bump pad 50 is formed to be wider than the upper surface 51 thereof, such that a risk that a neck will be cut by undercut may be eliminated, and a stable structure of the bump pad 50 may be implemented, thereby improving reliability.

The bump pad 50 may have a tapered shape in which a diameter thereof is increased from the upper surface 51 of the bump pad 50 toward the lower surface 52 thereof, that is, in a direction toward the insulating layer 200.

Meanwhile, a width W_{B} of the lower surface 52 of the bump pad 50 adjacent to the first circuit pattern 110 may be formed to be the same as or wider than a width W_{C} of the first circuit pattern 110.

The width W_{B} of the lower surface 52 of the bump pad 50 is formed to be the same as or wider than the width W_{C} of the first circuit pattern 110, such that the bump pad 50 may be stably formed, and a bonding area between the bump pad 50 and solder may be increased.

The coupling pad 80 may be embedded in the insulating layer 200 so as to come into contact with the lower surface 112 of the first circuit pattern 110.

According to an exemplary embodiment of the present disclosure, a width W_{P} of the coupling pad 80 may be formed to be wider than the width W_{C} of the first circuit pattern 110.

The coupling pad 80 having a width wider than the width W_{C} of the first circuit pattern 110 is formed so as to come into contact with the lower surface 112 of the first circuit pattern 110, such that the first circuit pattern 110 may be more stably embedded in the insulating layer 200.

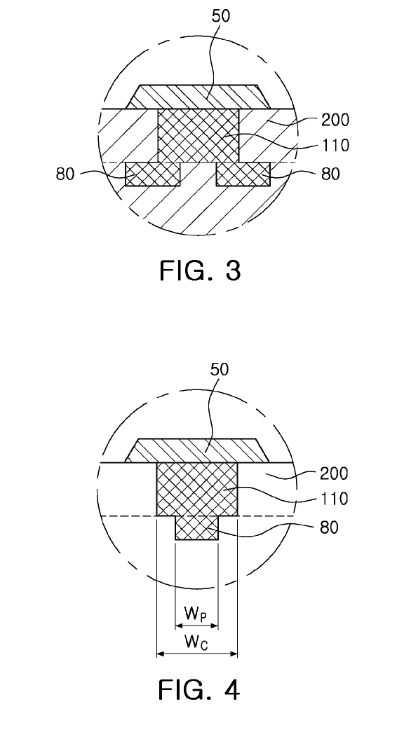

FIGS. 3 and 4 are partial cross-sectional views showing structures of coupling pads according to another exemplary embodiment of the present disclosure.

Referring to FIG. 3, a coupling pad 80 according to another exemplary embodiment of the present disclosure may be formed so as to come into contact with a portion of the lower surface 112 of the first circuit pattern 110.

Although the coupling pad 80 coming in contact with the portion of the lower surface 112 of the first circuit pattern 110 is shown in FIG. 3 in a form in which it comes in contact with edges of the lower surface 112 of the first circuit pattern 110, the present disclosure is not necessarily limited thereto. That is, a coupling pad coming in contact with the portion of the lower surface 112 of the first circuit pattern 110 in various forms may be formed.

Referring to FIG. 4, a coupling pad 80 according to another exemplary embodiment of the present disclosure may be formed on a central portion of the lower surface 112 of the first circuit pattern 110.

A width W_{P} of the coupling pad 80 formed on the central portion of the first circuit pattern 100 may be narrower than the width W_{C} of the first circuit pattern 110.

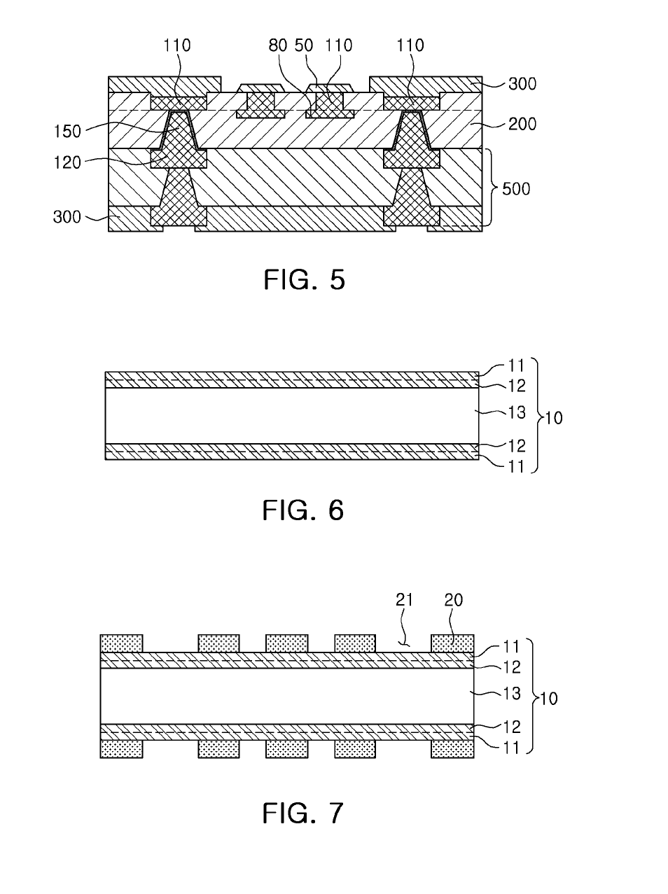

FIG. 5 is a cross-sectional view showing a structure of a printed circuit board according to another exemplary embodiment of the present disclosure.

Referring to FIG. 5, in the printed circuit board according to an exemplary embodiment of the present disclosure, a buildup layer 500 may be further stacked on the other surface of the insulating layer 200.

In this case, although the buildup layer 500 stacked on the other surface of the insulating layer 200 is shown as a single buildup layer in FIG. 5, the present disclosure is not limited thereto, but two or more buildup layers may be formed in a range in which those skilled in the art may apply the present disclosure.

Method of Manufacturing Printed Circuit Board

FIGS. 6 through 23 are views sequentially showing a method of manufacturing a printed circuit board according to an exemplary embodiment of the present disclosure.

Referring to FIG. 6, a carrier board 10 may be prepared.

The carrier board 10 may include a core part 13, inner-layer metal plates 12 disposed on both surfaces of the core part 13, and outer-layer metal plates 11 disposed on the inner-layer metal plates 12.

The inner-layer and outer-layer metal plates 12 and 11 may be formed of copper (Cu) foil, respectively, but are not necessarily limited thereto.

At least one surface of bonding surfaces of the inner-layer and outer-layer metal plates 12 and 11 may be surface-treated so that the inner-layer and outer-layer metal plates 12 and 11 may be easily separated from each other.

Referring to FIG. 7, a first plating resist 20 having opening parts 21 for forming a first circuit pattern 110 may be formed on the outer-layer metal plate 11.

As the first plating resist 20, which is a general photosensitive resist film, a dry film resist, or the like, may be used, but the present disclosure is not particularly limited thereto.

The first plating resist 20 having the opening parts 21 may be formed by applying a photosensitive resist film, forming a patterning mask, and then performing an exposure and development process.

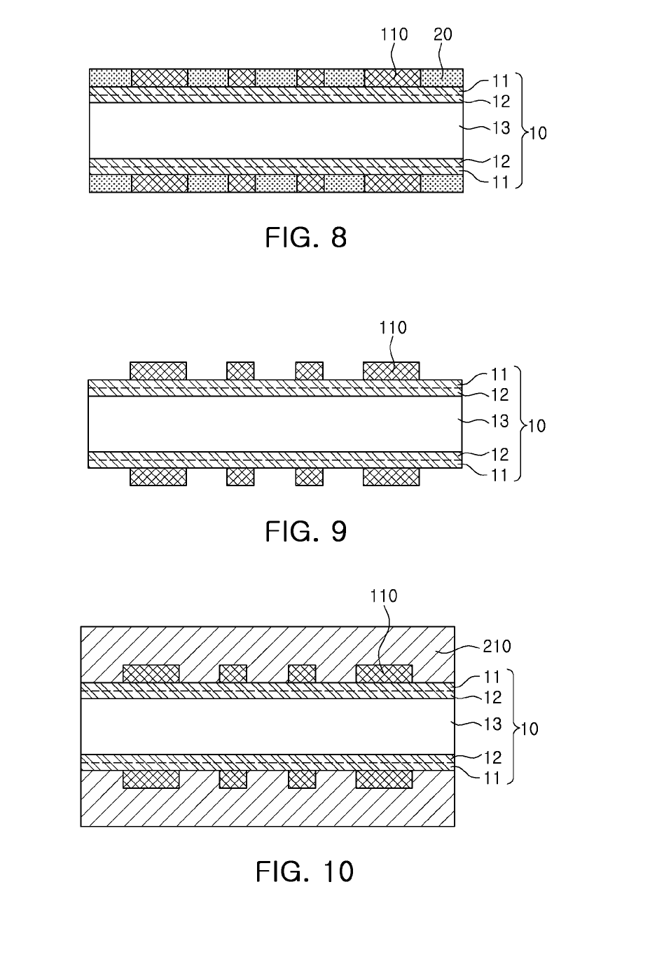

Referring to FIG. 8, a first circuit pattern 110 may be formed by filling the opening parts 21 with a conductive metal.

The filling of the conductive metal may be performed, for example, by applying an electroplating process, or the like, and as the conductive metal, any metal may be used without limitation as long as it has excellent conductivity. For example, copper (Cu) may be used.

Referring to FIG. 9, the first plating resist 20 may be removed.

Referring to FIG. 10, a first insulating layer 210 covering the first circuit pattern 110 may be formed on the outer-layer metal plate 11 on which the first circuit pattern 110 is formed.

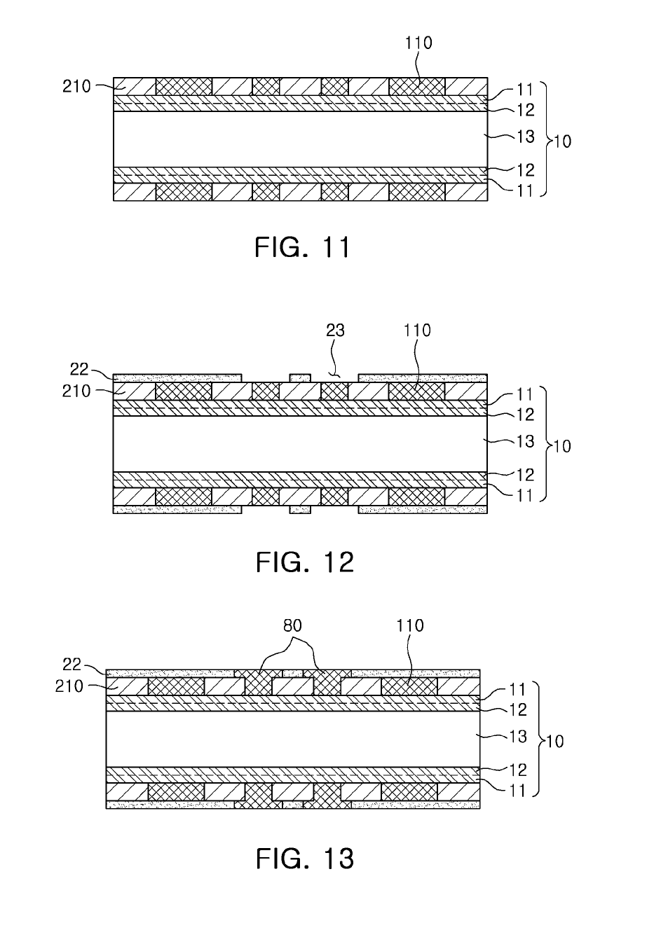

Referring to FIG. 11, a surface of the first insulating layer 210 may be ground so that one surface of the first circuit pattern 110 is exposed.

The surface of the first insulating layer 210 may be ground so that one surface of the first circuit pattern 110 and the surface of the first insulating layer 210 are positioned on the same plane as each other.

However, the present disclosure is not limited thereto. That is, any process may be applied as long as the process may expose one surface of the first circuit pattern 110 to one surface of the first insulating layer 210 in order to form a coupling pad 80 coming in contact with the first circuit pattern 110.

Referring to FIG. 12, a second plating resist 22 having opening parts 23 for forming the coupling pad 80 may be formed on the first insulating layer 210.

Referring to FIG. 13, the coupling pad 80 may be formed by filling the opening parts 23 with a conductive metal.

The circuit pattern embedded at the time of assembly is not detached but may be stably embedded by forming the coupling pad 80 coming in contact with the first circuit pattern 110.

The coupling pad 80 may be formed so as to have a width W_{P} wider than a width W_{C} of the first circuit pattern 110. In addition, the coupling pad 80 may be formed so as to come into contact with a portion of the first circuit pattern 110.

A shape of the coupling pad 80 may be adjusted by patterning the second plating resist 22 having the opening parts 23 for forming the coupling pad 80 in various shapes.

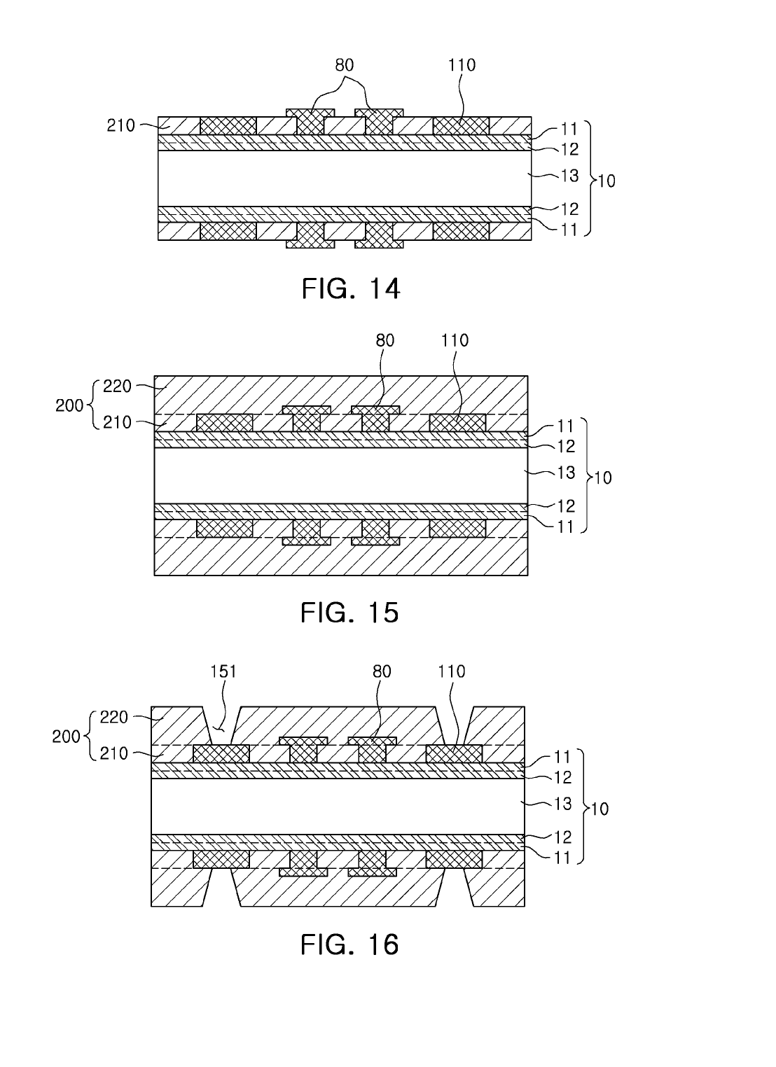

Referring to FIG. 14, the second plating resist 22 may be removed.

Referring to FIG. 15, a second insulating layer 220 covering the coupling pad 80 may be formed on the first insulating layer 210.

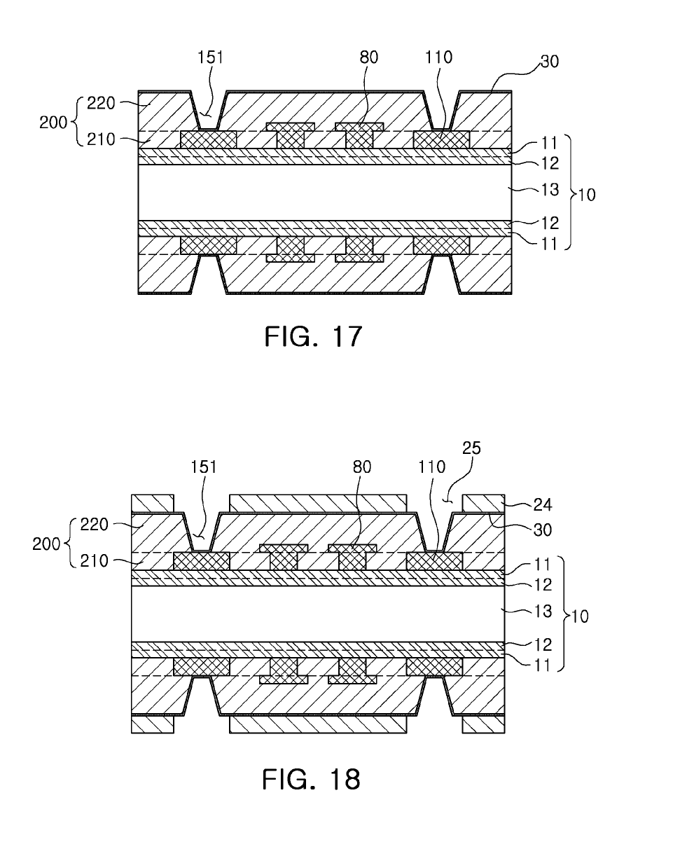

Referring to FIG. 16, a via hole 151 may be formed in the second insulating layer 220 so that portions of the first circuit pattern 110 are exposed.

In this case, the via hole 151 may be formed by a mechanical drill or a laser drill, but is not particularly limited thereto.

Here, the laser drill may be a CO₂ laser drill or YAG laser drill, but is not particularly limited thereto.

Although the case in which the via hole 151 has a tapered shape in which a diameter thereof is decreased toward a lower surface is shown in FIG. 16, the via hole may have any shape known in the art such as a tapered shape in which a diameter thereof is increased toward a lower surface, a cylindrical shape, and the like.

Referring to FIG. 17, a seed layer 30 may be formed on the second insulating layer 220 in which the via hole 151 is formed.

The seed layer 30 may be formed by performing an electroless plating process, but is not particularly limited thereto.

Referring to FIG. 18, a third plating resist 24 having opening parts 25 for forming a second circuit pattern 120 may be formed on the second insulating layer 220 on which the seed layer 30 is formed.

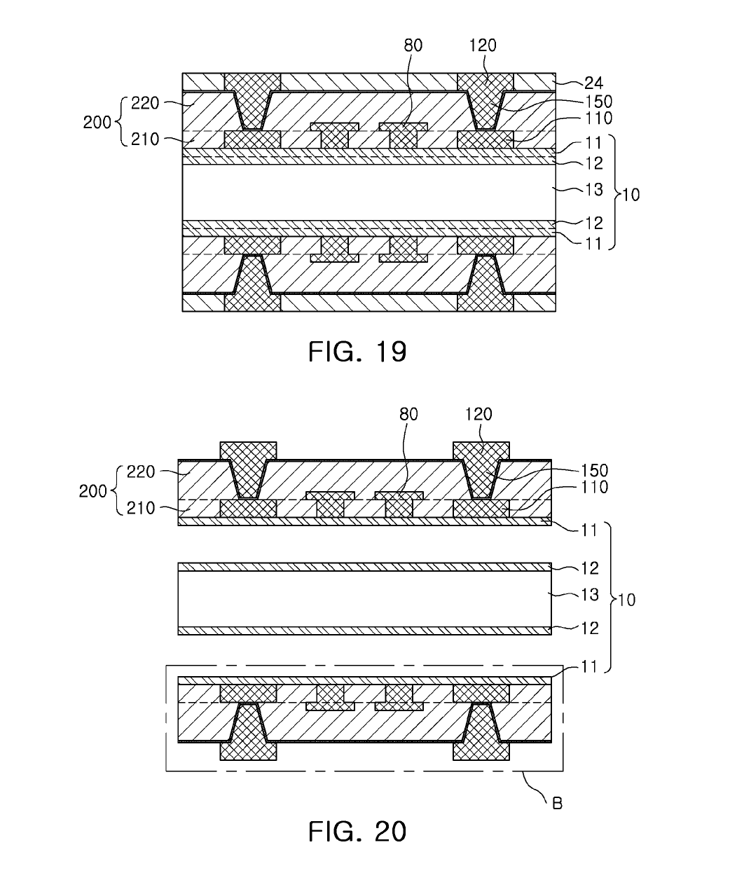

Referring to FIG. 19, a via 150 may be formed by filling the via hole 151, and a second circuit pattern 120 may be formed by filling the opening parts 25.

The via 150 and the second circuit pattern 120 may be formed by filling a conductive metal by performing an electroplating process, or the like, wherein as the conductive metal, any metal may be used as long as it has excellent electric conductivity. For example, copper (Cu) may be used.

The first and second circuit patterns 110 and 120 may be electrically connected to each other through the via 150.

After the second circuit pattern 120 is formed, the third plating resist 24 may be removed.

A buildup layer 500 may be further formed by repeating the above-mentioned process for forming the via and the circuit pattern (not shown). In this case, the stacked buildup layer may be composed of three layers, four layers, or the like, in a range in which those in the skilled art may apply the present disclosure, as well as two layers.

Referring to FIG. 20, the inner-layer metal plate 12 and the outer-layer metal plate 11 may be separated from each other.

In this case, the inner-layer metal plate 12 and the outer-layer metal plate 11 may be separated using a blade, but the present disclosure is not limited thereto. All of the methods known in the art may be used.

Next, a bump pad 50 may be selectively formed on portions of the first circuit pattern 110 by selectively etching an outer-layer metal plate 11 on a separated printed circuit board B.

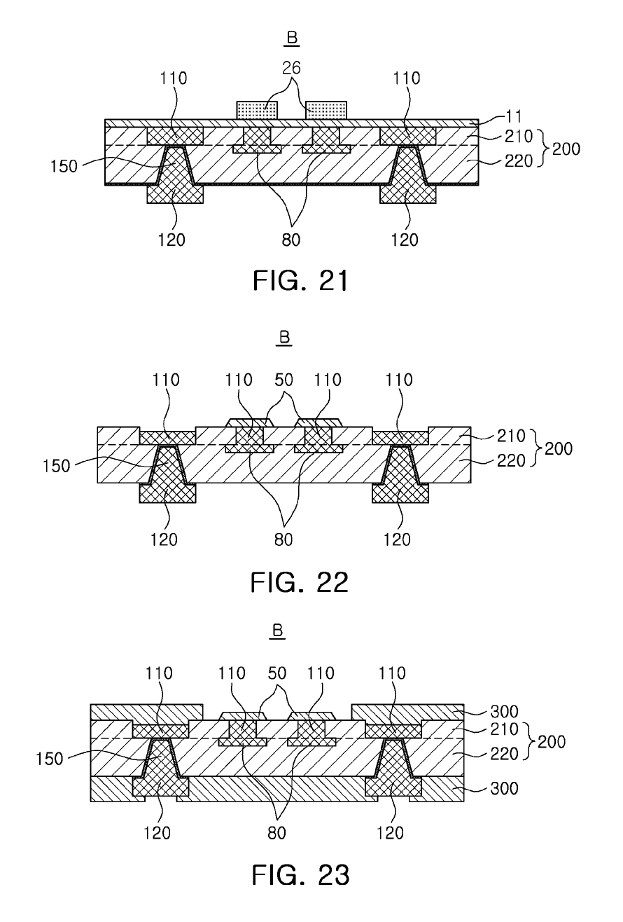

Referring to FIG. 21, in order to selectively form the bump pad 50, according to an exemplary embodiment of the present disclosure, an etching resist 26 may be formed on the other surface of the outer-layer metal plate 11 opposing one surface of the outer-layer metal plate 11 on which the first circuit pattern 110 is formed.

The etching resist 26 may only be formed in portions of regions in which portions of the first circuit pattern 110 to be formed with the bump pad 50 are positioned.

In this case, the etching resist 26 may be formed to have a width wider than that of the first circuit pattern 110.

As the etching resist 26, which is a general photosensitive resist film, a dry film resist, or the like, may be used, but the present disclosure is not particularly limited thereto.

The etching resist 26 may be formed only in portions of regions in which portions of the first circuit pattern 110 to be formed with the bump pad 50 are positioned by applying a photosensitive resist film, forming a patterning mask, and then performing an exposure and development process.

Referring to FIG. 22, the bump pad 50 may be formed by etching the outer-layer metal plate 11 to remove the outer-layer metal plate 11 from regions in which the etching resist 26 is not formed.

The outer-layer metal plate 11 at regions on which the etching resist 26 is not formed is removed, and the outer-layer metal plate 11 at regions on which the etching resist 26 is formed is not be removed but remains, such that the bump pad 50 may be formed.

An upper surface of the first circuit pattern 110 embedded in the insulating layer 200 may be exposed to one surface of the insulating layer 200 in the region in which the outer-layer metal plate 11 is removed. In this case, the upper surface of the first circuit pattern 110 may be positioned on the same level or a level lower than one surface of the insulating layer 200. During a process of etching the outer-layer metal plate, the first circuit pattern 110 may be over-etched, such that a step between the first circuit pattern 110 and the insulating layer 200 may be generated.

The selectively formed bump pad 50 may be formed of a metal plate that is not removed but remains in the outer-layer metal plate 11.

The bump pad 50 formed of the metal plate, which is not etched but remains, is formed to protrude from one surface of the insulating layer 200, such that connectivity with a mounted component, or the like, may be improved.

Meanwhile, a width W_{B} of a lower surface 52 of the bump pad 50 adjacent to the first circuit pattern 110 may be the same as or wider than the width W_{C} of the first circuit pattern 110. The width of the bump pad 50 may be controlled by adjusting a width of the etching resist 26.

The bump pad 50 may be formed so that the lower surface 52 thereof is wider than that of an upper surface 51 thereof.

The lower surface 52 of the bump pad 50 is formed to be wider than the upper surface 51 thereof, such that a risk that a neck will be cut by undercut may be eliminated, and a stable structure of the bump pad 50 may be implemented, thereby improving reliability.

The bump pad 50 may have a tapered shape in which a diameter thereof is increased from the upper surface 51 of the bump pad 50 toward the lower surface 52 thereof, that is, in a direction toward the insulating layer 200.

Referring to FIG. 23, a solder resist 300 may be formed on a surface of the printed circuit board B so that circuit patterns for a connection pad among the first and second circuit patterns 110 and 120 are exposed.

As set forth above, according to exemplary embodiments of the present disclosure, the circuit pattern is stably embedded in the insulating layer, such that the defect that the circuit pattern is detached at the time of assembly may be prevented, and the bump pad having a protruding shape may be selectively formed, such that connectivity with the mounted component, or the like, may be improved.

While exemplary embodiments have been shown and described above, it will be apparent to those skilled in the art that modifications and variations could be made without departing from the scope of the present invention as defined by the appended claims.

What is claimed is:

1. A printed circuit board comprising:
a first circuit pattern embedded in an insulating layer wherein an upper surface of the first circuit pattern is exposed to an upper surface of the insulating layer;
a coupling pad embedded in the insulating layer to come into contact with a lower surface of the first circuit pattern; and
a bump pad formed on the upper surface of the first circuit pattern to protrude above the upper surface of the insulating layer.

2. The printed circuit board of claim 1, wherein a lower surface of the bump pad adjacent to the first circuit pattern is wider than an area of an upper surface of the bump pad.

3. The printed circuit board of claim 1, wherein a diameter of the bump pad is increased in a direction toward the insulating layer.

4. The printed circuit board of claim 1, wherein a width of a lower surface of the bump pad adjacent to the first circuit pattern is the same as or wider than a width of the first circuit pattern.

5. The printed circuit board of claim 1, wherein a width of the coupling pad is wider than a width of the first circuit pattern.

6. The printed circuit board of claim 1, wherein the coupling pad comes into contact with a portion of the lower surface of the first circuit pattern.

7. The printed circuit board of claim 1, wherein the upper surface of the first circuit pattern exposed to the upper surface of the insulating layer is positioned on the same level or at a level lower than the upper surface of the insulating layer.

8. A method of manufacturing a printed circuit board, the method comprising:
forming a first circuit pattern on one surface of a metal plate;
forming a first insulating layer on the one surface of the metal plate such that one surface of the first circuit pattern is exposed;
forming a coupling pad on the one surface of the first circuit pattern; and
selectively etching the metal plate to form a bump pad on portions of the first circuit pattern.

9. The method of claim 8, wherein the forming of the first insulating layer on the metal plate so that one surface of the first circuit pattern is exposed includes:
forming a first insulating layer covering the first circuit pattern on one surface of the metal plate; and
grinding a surface of the first insulating layer such that one surface of the first circuit pattern is exposed.

10. The method of claim 9, wherein in the grinding of the surface of the first insulating layer, the surface of the first insulating layer is ground so that the one surface of the first circuit pattern and the surface of the first insulating layer are positioned on the same plane.

11. The method of claim 8, wherein the selective etching of the metal plate to form the bump pad on portions of the first circuit pattern includes:
forming an etching resist on portions of the other surface opposing one surface of the metal plate; and
etching the metal plate to remove regions in which the etching resist is not formed.

12. The method of claim 8, wherein the bump pad is a metal plate that remains in the metal plate after selective etching of the metal plate.

13. The method of claim 8, wherein a lower surface of the bump pad adjacent to the first circuit pattern is wider than an area of an upper surface of the bump pad.

14. The method of claim 8, wherein a width of a lower surface of the bump pad adjacent to the first circuit pattern is the same as or wider than a width of the first circuit pattern.

15. The method of claim 8, wherein a width of the coupling pad is wider than a width of the first circuit pattern.

16. The method of claim 8, wherein the coupling pad is formed to come into contact with a portion of the first circuit pattern.

17. The method of claim 8, further comprising:
forming a second insulating layer covering the coupling pad on the first insulating layer; and
forming a via penetrating through the second insulating layer and a second circuit pattern.

18. A printed circuit board comprising:
a first circuit pattern embedded in an insulating layer wherein an upper surface of the first circuit pattern is exposed to an upper surface of the insulating layer;
a coupling pad embedded in the insulating layer to come into contact with a lower surface of the first circuit pattern; and
a bump pad formed on the upper surface of the first circuit pattern, wherein an upper surface of the bump pad has a different a width from that of which a lower surface of the bump pad.

19. The printed circuit board of claim 18, wherein the width of the upper surface of the bump pad is smaller than the width of the lower surface of the bump pad.

20. The printed circuit board of claim 18, wherein the bump pad has a trapezoidal side view.
